(19) United States
(12) Patent Application Publication
(10) Pub. No.: US 2019/0198765 A1
(43) Pub. Date: Jun. 27, 2019

(54) PROCESS FOR MAKING AN ORGANIC CHARGE TRANSPORTING FILM

(71) Applicants: Dow Global Technologies LLC, Midland, MI (US); ROHM AND HAAS ELECTRONIC MATERIALS KOREA LTD., Chungcheongnam-do, Cheonan (KR); Rohm and Hass Electonic Materials LLC, Marlborough, MA (US)

(72) Inventors: David D. DEVORE, Midland, MI (US); Yoo Jin DOH, Seoul (KR); Shaoguang FENG, Shanghai (CN); David D. GRIGG, Midland, MI (US); Yang LI, Shanghai (CN); Chun LIU, Midland, MI (US); Sukrit MUKHOPADHYAY, Midland, MI (US); Hong-Yeop NA, Cheonan (KR); Matthew S. REMY, Midland, MI (US); Liam P. SPENCER, Freeport, TX (US); Anatoliy N. SOKOLOV, Midland, MI (US); Peter TREFONAS, III, Medway, MA (US); Minrong ZHU, Shanghai (CN); Ashely INMAN, Midland, MI (US); John W. KRAMER, Midland, MI (US)

(21) Appl. No.: 16/309,001

(22) PCT Filed: Jun. 28, 2016
(86) PCT No.: PCT/CN2016/087410

§ 371 Date: Dec. 11, 2018

(51) Int. Cl. H01L 51/00

(52) U.S. Cl. CPC H01L 51/0035; H01L 51/5056; H01L 51/006; H01L 51/0072

(57) ABSTRACT

A single liquid phase formulation useful for producing an organic charge transporting film. The formulation contains: (a) a polymer having Mₙ at least 4,000 and comprising polymerized units of a compound of formula NAr¹Ar²Ar³, wherein Ar¹, Ar² and Ar³ independently are C₆-C₅₀ aromatic substituents and at least one of Ar¹, Ar² and Ar³ contains a vinyl group attached to an aromatic ring; provided that said compound contains no arylmethoxy linkages; (b) an acid catalyst which is is an organic Bronsted acid with pKa≤4; a Lewis acid comprising a positive aromatic ion and an anion which is (i) a tetraaryl borate having the formula (I) wherein R represents zero to five non-hydrogen substituents selected from D, F and CF₃, (ii) BF₄⁻, (iii) PF₆⁻, (iv) SbF₆⁻, (v) AsF₆⁻ or (vi) ClO₄⁻; or a thermal acid generator.

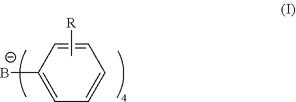

### FIELD OF THE INVENTION

The present invention relates to a process for preparing an organic charge transporting film.

### BACKGROUND OF THE INVENTION

There is a need for an efficient process for manufacturing an organic charge transporting film for use in a flat panel organic light emitting diode (OLED) display. Solution processing is one of the leading technologies for fabricating large flat panel OLED displays by deposition of OLED solution onto a substrate to form a thin film followed by cross-linking and polymerization. Currently, solution processable polymeric materials are cross-linkable organic charge transporting compounds. For example, U.S. Pat. No. 7,037,994 discloses an antireflection film-forming formulation comprising at least one polymer containing an acetoxymethylacenaphthylene or hydroxyl methyl acenaphthylene repeating unit and a thermal or photo acid generator (TAG, PAG) in a solvent. However, this reference does not disclose the formulation described herein.

### SUMMARY OF THE INVENTION

The present invention provides a single liquid phase formulation useful for producing an organic charge transporting film; said formulation comprising: (a) a polymer having Mₙ at least 4,000 and comprising polymerized units of a compound of formula NAr¹Ar²Ar³, wherein Ar¹, Ar² and Ar^{a} independently are C₆-C₅₀ aromatic substituents and at least one of Ar¹, Ar² and Ar^{a} contains a vinyl group attached to an aromatic ring; provided that said compound contains no arylmethoxy linkages; (b) an acid catalyst which is an organic Bronsted acid with pKa≤2; a Lewis acid comprising a positive aromatic ion and an anion which is (i) a tetraaryl borate having the formula

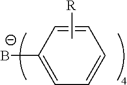

wherein R represents zero to five non-hydrogen substituents selected from D, F and CF₃, (ii) BF₄⁻, (iii) PF₆⁻, (iv) SbF₆⁻, (v) AsF₆⁻ or (vi) ClO₄⁻; or a thermal acid generator (TAG) which is an ammonium or pyridinium salt of an organic Bronsted acid with pKa≤4 or an ester of an organic sulfonic acid; and (c) a solvent.

### DETAILED DESCRIPTION OF THE INVENTION

Percentages are weight percentages (wt %) and temperatures are in ° C., unless specified otherwise. Operations were performed at room temperature (20-25° C.), unless specified otherwise. Boiling points are measured at atmospheric pressure (ca. 101 kPa). Molecular weights are in Daltons and molecular weights of polymers are determined by Size Exclusion Chromatography using polystyrene standards.

As used herein, the term “aromatic substituent” refers to a substituent having at least one aromatic ring, preferably at least two. A cyclic moiety which contains two or more fused rings is considered to be a single aromatic ring, provided that all ring atoms in the cyclic moiety are part of the aromatic system. For example, naphthyl, carbazolyl and indolyl are considered to be single aromatic rings, but fluorenyl is considered to contain two aromatic rings because the carbon atom at the 9-position of fluorene is not part of the aromatic system.

Preferably, the compound of formula NAr¹Ar²Ar³ contains a total of 4 to 20 aromatic rings; preferably at least 5 preferably at least 6; preferably no more than 18, preferably no more than 15, preferably no more than 13. Preferably, each of Ar¹, Ar² and Ar³ independently contains at least 10 carbon atoms, preferably at least 12; preferably no more than 45, preferably no more than 42, preferably no more than 40. In a preferred embodiment, each of Ar² and Ar³ independently contains at least 10 carbon atoms, preferably at least 15, preferably at least 20; preferably no more than 45, preferably no more than 42, preferably no more than 40; and Ar¹ contains no more than 35 carbon atoms, preferably no more than 25, preferably no more than 15. Aliphatic carbon atoms, e.g., C₁-C₆ hydrocarbyl substituents or non-aromatic ring carbon atoms (e.g., the 9-carbon of fluorene), are included in the total number of carbon atoms in an Ar substituent. Ar groups may contain heteroatoms, preferably N, O or S; preferably N; preferably Ar groups contain no heteroatoms other than nitrogen. Preferably, only one vinyl group is present in the compound of formula NAr¹Ar²Ar³. Preferably, Ar groups comprise one or more of biphenylyl, fluorenyl, phenylenyl, carbazolyl and indolyl. In a preferred embodiment of the invention, two of Ar¹, Ar² and Ar³ are connected by at least one covalent bond. An example of this is the structure shown below

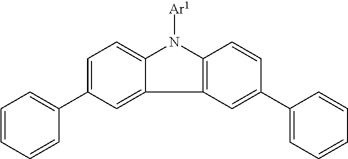

When a nitrogen atom in one of the aryl substituents is a triarylamine nitrogen atom, the Ar¹, Ar² and Ar³ groups can be defined in different ways depending on which nitrogen atom is considered to be the nitrogen atom in the formula NAr¹Ar²Ar³. In this case, the nitrogen atom and Ar groups are to be construed so as to satisfy the claim limitations.

Preferably, Ar¹, Ar² and Ar³ collectively contain no more than five nitrogen atoms, preferably no more than four, preferably no more than three.

The compound of formula NAr¹Ar²Ar³ contains no arylmethoxy linkages. An arylmethoxy linkage is an ether linkage having two benzylic carbon atoms attached to an oxygen atom. A benzylic carbon atom is a carbon atom which is not part of an aromatic ring and which is attached to a ring carbon of an aromatic ring having from 5 to 30 carbon atoms (preferably 5 to 20), preferably a benzene ring. Preferably, the compound contains no linkages having only one benzylic carbon atom attached to an oxygen atom. Preferably, an arylmethoxy linkage is an ether, ester or alcohol. Preferably, the compound of formula NAr¹Ar²Ar³ has no ether linkages where either carbon is a benzylic carbon, preferably no ether linkages at all.

An “organic charge transporting compound” is a material which is capable of accepting an electrical charge and transporting it through the charge transport layer. Examples of charge transporting compounds include “electron transporting compounds” which are charge transporting compounds capable of accepting an electron and transporting it through the charge transport layer, and “hole transporting compounds” which are charge transporting compounds capable of transporting a positive charge through the charge transport layer. Preferably, organic charge transporting compounds. Preferably, organic charge transporting compounds have at least 50 wt % aromatic rings (measured as the molecular weight of all aromatic rings divided by total molecular weight; non-aromatic rings fused to aromatic rings are included in the molecular weight of aromatic rings), preferably at least 60%, preferably at least 70%, preferably at least 80%, preferably at least 90%. Preferably the polymer comprises organic charge transporting compounds.

In a preferred embodiment of the invention, some or all materials used, including solvents and polymers, are enriched in deuterium beyond its natural isotopic abundance. All compound names and structures which appear herein are intended to include all partially or completely deuterated analogs.

Preferably, the polymer has Mₙ at least 6,000, preferably at least 8,000, preferably at least 10,000; preferably at least 20,000 no greater than 10,000,000, preferably no greater than 1,000,000, preferably no greater than 500,000, preferably no greater than 100,000. Preferably, the polymer comprises at least 60% (preferably at least 80%, preferably at least 95%) polymerized monomers which contain at least five aromatic rings, preferably at least six; other monomers not having this characteristic may also be present.

Preferably, the polymers are at least 99% pure, as measured by liquid chromatography/mass spectrometry (LC/MS) on a solids basis, preferably at least 99.5%, preferably at least 99.7%. Preferably, the formulation of this invention contains no more than 10 ppm of metals, preferably no more than 5 ppm.

Preferred polymers useful in the present invention include, e.g., the following structures.

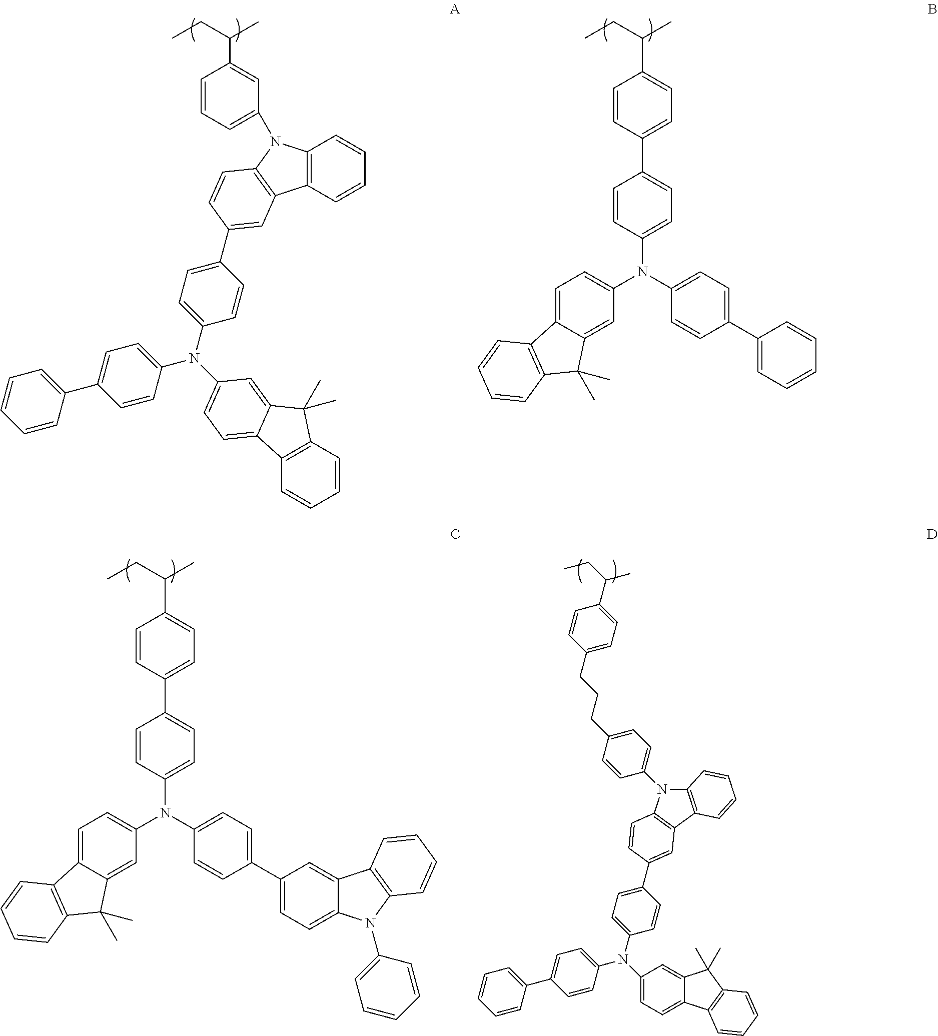

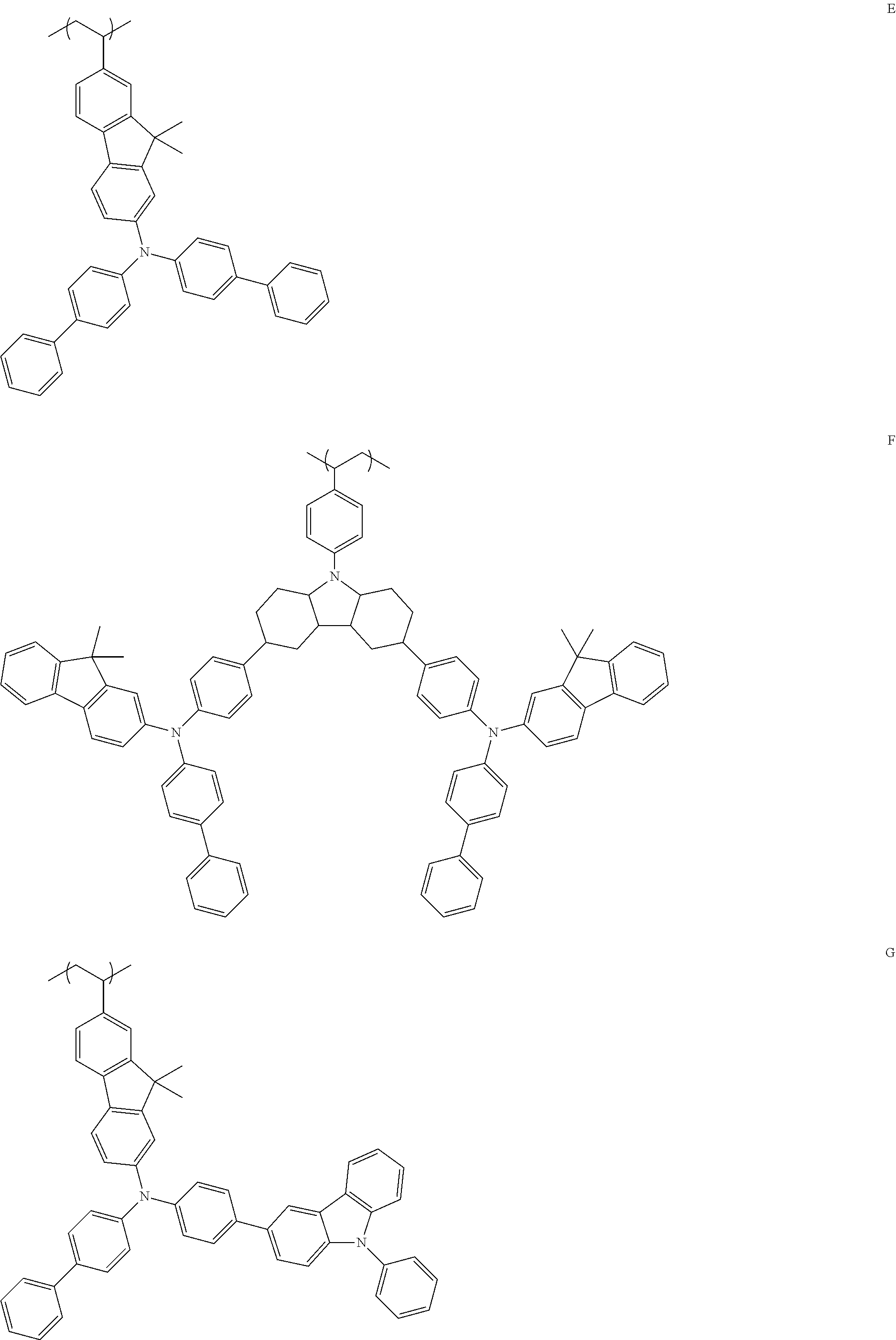

Crosslinking agents which are not necessarily charge transporting compounds may be included in the formulation as well. Preferably, these crosslinking agents have at least 60 wt % aromatic rings (as defined previously), preferably at least 70%, preferably at least 75 wt %. Preferably, the crosslinking agents have from three to five polymerizable groups, preferably three or four. Preferably, the polymerizable groups are ethenyl groups attached to aromatic rings. Preferred crosslinking agents are shown below

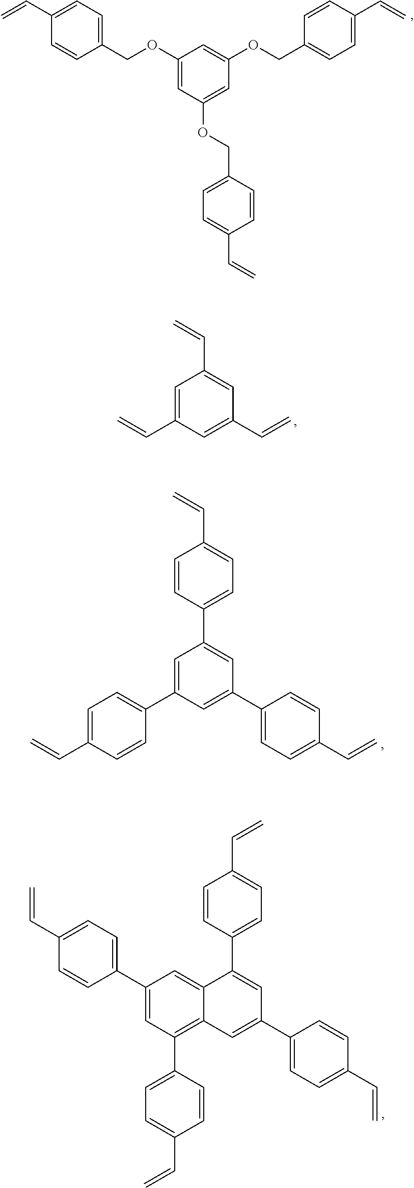

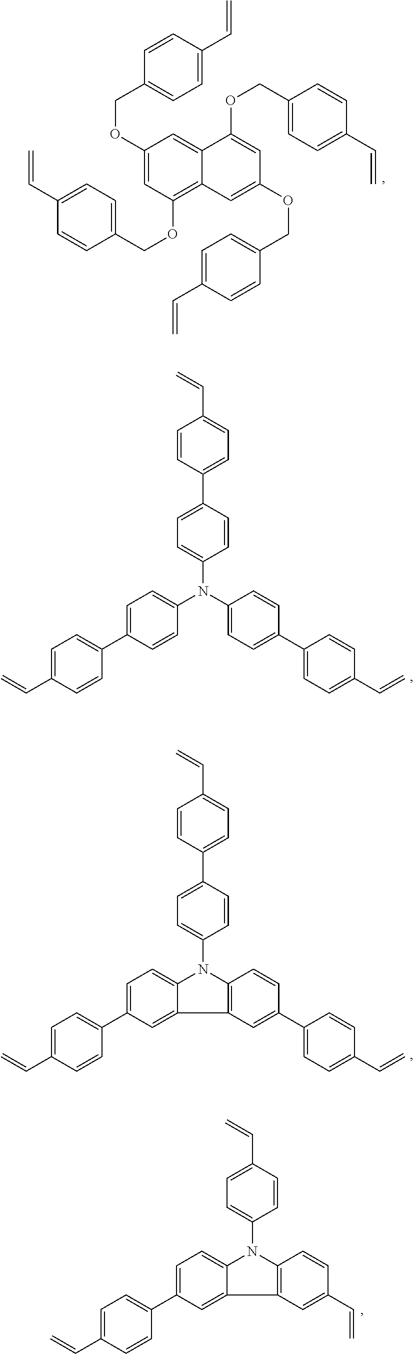

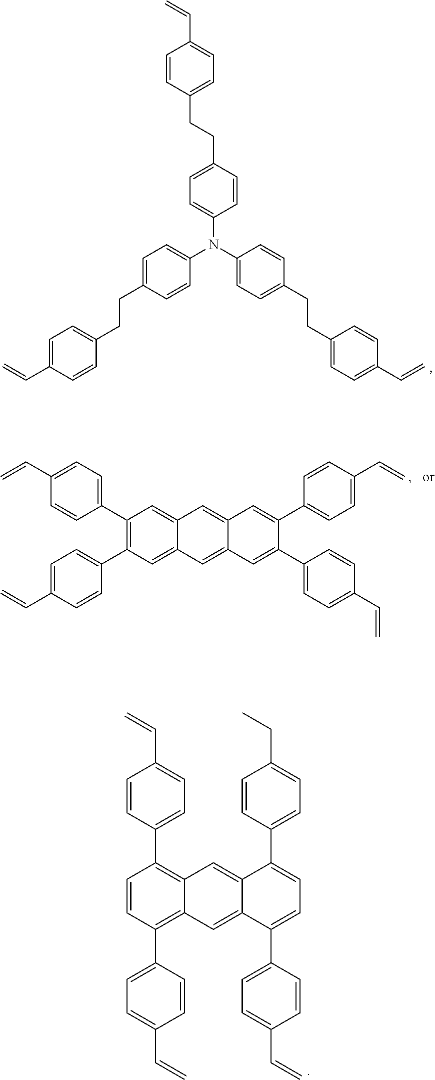

Preferably, the anion is a tetraaryl borate having the formula

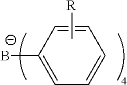

wherein R represents zero to five non-hydrogen substituents selected from F and CF₃. Preferably, R represents five substituents on each of four rings, preferably five fluoro substituents.

Preferably, the positive aromatic ion has from seven to fifty carbon atoms, preferably seven to forty. In a preferred embodiment, the positive aromatic ion is tropylium ion or an ion having the formula

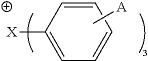

wherein A is a substituent on one or more of the aromatic rings and is H, D, CN, CF₃ or (Ph)₃C+ (attached via Ph); X is C, Si, Ge or Sn. Preferably, X is C. Preferably, A is the same on all three rings.

Preferably, the organic Bronsted acid has pKa≤2, preferably ≤0. Preferably, the organic Bronsted acid is an aromatic, alkyl or perfluoroalkyl sulfonic acid; a carboxylic acid; a protonated ether; or a compound of formula Ar⁴SO₃CH₂Ar⁵, wherein Ar⁴ is phenyl, alkylphenyl or trifluoromethylphenyl, and Ar⁵ is nitrophenyl. Preferably, an ester of an organic sulfonic acid is a substituted benzyl ester (preferably a nitrobenzyl ester) of an aromatic sulfonic acid. Preferably, a TAG has a degradation temperature≤280° C. Especially preferred acid catalysts for use in the present invention include, e.g., the following Bronsted acid, Lewis acid and TAGS.

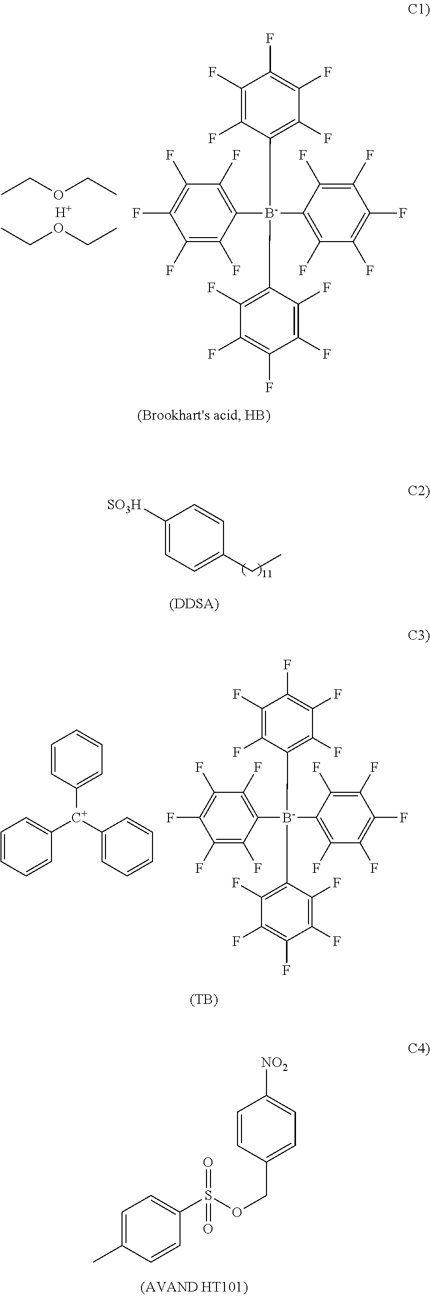

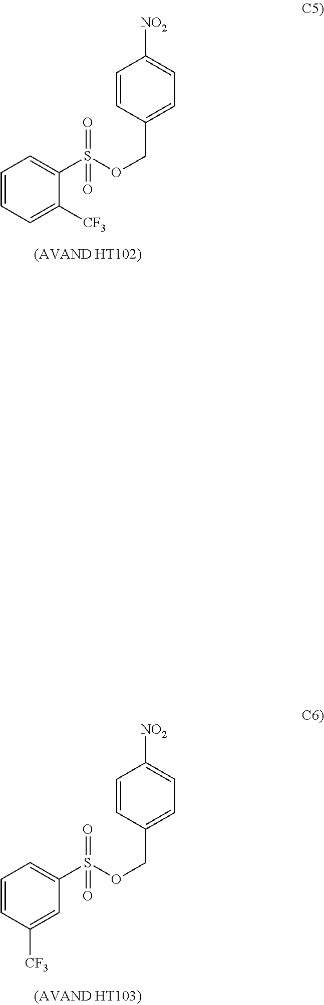 [SMILES: O=[N+]([O-])c1ccc(COS(=O)(=O)c2ccccc2C(F)(F)F)cc1 ; O=[N+]([O-])c1ccc(COS(=O)(=O)c2cccc(C(F)(F)F)c2)cc1]

An especially preferred TAG is an organic ammonium salt. Preferred pyridinium salts include, e.g.,

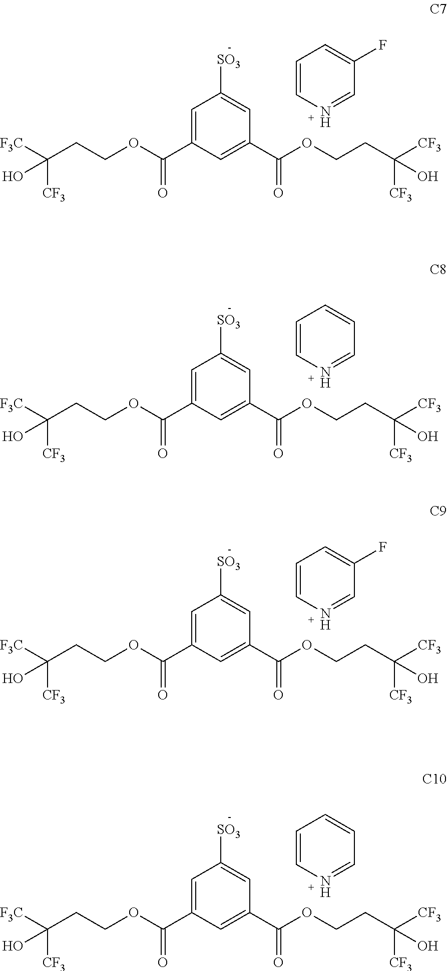

Preferably, the amount of acid is from 0.5 to 10 wt % of the weight of the polymer, preferably less than 5 wt %, preferably less than 2 wt %.

Preferably, solvents used in the formulation have a purity of at least 99.8%, as measured by gas chromatography-mass spectrometry (GC/MS), preferably at least 99.9%. Preferably, solvents have an RED value relative to polymer (relative energy difference as calculated from Hansen solubility parameter calculated using CHEMCOMP v2.8.50223.1) less than 1.2, preferably less than 1.0. Preferred solvents include aromatic hydrocarbons and aromatic-aliphatic ethers, preferably those having from six to twenty carbon atoms. Anisole, xylene and toluene are especially preferred solvents.

Preferably, the percent solids of the formulation, i.e., the percentage of polymers and acid catalyst relative to the total weight of the formulation, is from 0.5 to 20 wt %; preferably at least 0.8 wt %, preferably at least 1 wt %, preferably at least 1.5 wt %; preferably no more than 15 we/0, preferably no more than 10 wt %, preferably no more than 7 wt %, preferably no more than 4 wt %. Preferably, the amount of solvent(s) is from 80 to 99.5 wt %; preferably at least 85 wt %, preferably at least 90 wt %, preferably at least 93 wt %, preferably at least 94 wt %; preferably no more than 99.2 wt %, preferably no more than 99 wt %, preferably no more than 98.5 wt %.

The present invention is further directed to an organic charge transporting film and a process for producing it by coating the formulation on a surface, preferably another organic charge transporting film, and Indium-Tin-Oxide (ITO) glass or a silicon wafer. The film is formed by coating the formulation on a surface, prebaking at a temperature from 50 to 150° C. (preferably 80 to 120° C.), preferably for less than five minutes, followed by thermal annealing at a temperature from 120 to 280° C.; preferably at least 140° C., preferably at least 160° C., preferably at least 170° C.; preferably no greater than 230° C., preferably no greater than 215° C.

Preferably, the thickness of the polymer films produced according to this invention is from 1 nm to 100 microns, preferably at least 10 nm, preferably at least 30 nm, preferably no greater than 10 microns, preferably no greater than 1 micron, preferably no greater than 300 nm. The spin-coated film thickness is determined mainly by the solid contents in solution and the spin rate. For example, at a 2000 rpm spin rate, 2, 5, 8 and 10 wt % polymer formulated solutions result in the film thickness of 30, 90, 160 and 220 nm, respectively. The wet film shrinks by 5% or less after baking and annealing.

### EXAMPLES

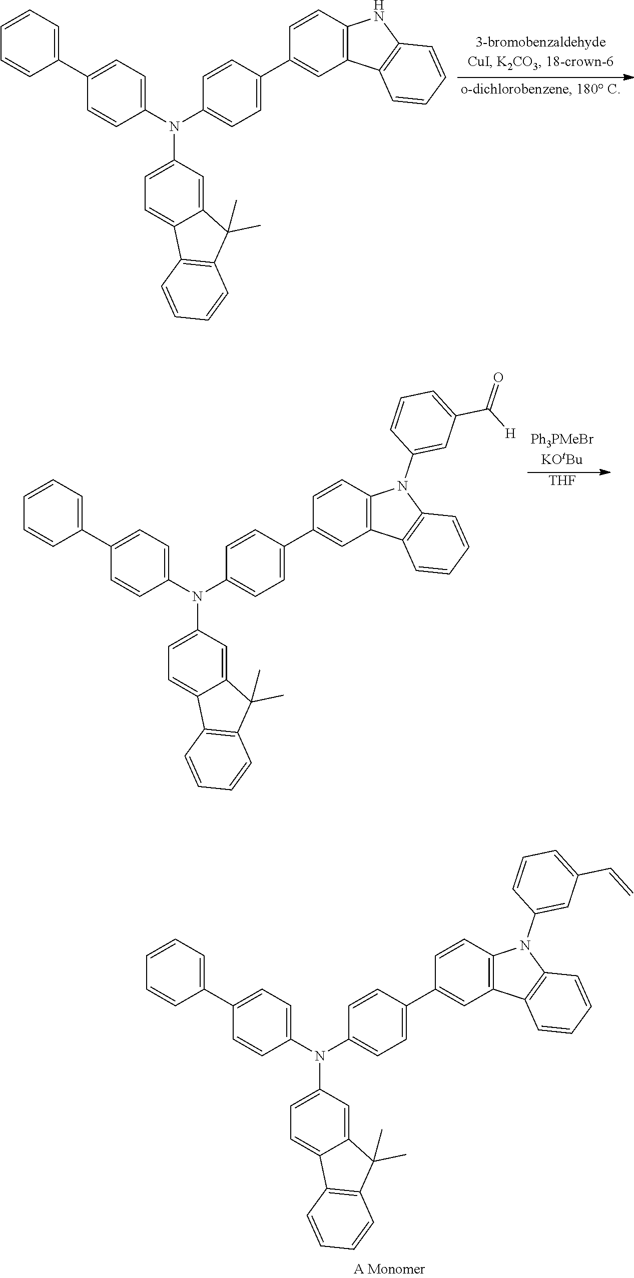 [SMILES: CC1(C)c2ccccc2-c2ccc(N(c3ccc(-c4ccccc4)cc3)c3ccc(-c4ccc5[nH]c6ccccc6c5c4)cc3)cc21 ; CC1(C)c2ccccc2-c2ccc(N(c3ccc(-c4ccccc4)cc3)c3ccc(-c4ccc5c(c4)c4ccccc4n5-c4cccc(C=O)c4)cc3)cc21 ; "THF" ; C=Cc1cccc(-n2c3ccccc3c3cc(-c4ccc(N(c5ccc(-c6ccccc6)cc5)c5ccc6c(c5)C(C)(C)c5ccccc5-6)cc4)ccc32)c1]

### Synthesis of 3-(3-(4-([1,1′-biphenyl]-4-yl(9,9-dimethyl-9H-fluoren-2-yl)amino)phenyl)-9H-carbazol-9-yl)benzaldehyde

A round bottom flask was charged with carbazole (9.10 g, 15.1 mmol, 1.0 equiv), 3-bromobenzaldehyde (2.11 mL, 18.1 mmol, 1.2 equiv), CuI (0.575 g, 3.02 mmol, 0.2 equiv), potassium carbonate (6.26 g, 45.3 mmol, 3.0 equiv), and 18-crown-6 (399 mg, 10 mol %). The flask was flushed with nitrogen and connected to a reflux condenser. 55 mL of dry, degassed, 1,2-dichlorobenzene was added, and the mixture was heated to 180° C. overnight. Only partial conversion was noted after 14 hours. An additional 2.1 mL of 3-bromobenzaldehyde was added, and heated continued another 24 hours. The solution was cooled and filtered to remove solids. The filtrate was concentrated and adsorbed onto silica for purification by chromatography (0 to 60% dichloromethane in hexanes), which delivered product as a pale yellow solid (8.15 g, 74%). ¹H NMR (500 MHz, CDCl₃) δ 10.13 (s, 1H), 8.39-8.32 (m, 1H), 8.20 (dd, J=7.8, 1.0 Hz, 1H), 8.13 (t, J=1.9 Hz, 1H), 7.99 (d, J=7.5 Hz, 1H), 7.91-7.86 (m, 1H), 7.80 (t, J=7.7 Hz, 1H), 7.70-7.58 (m, 7H), 7.56-7.50 (m, 2H), 7.47-7.37 (m, 6H), 7.36-7.22 (m, 9H), 7.14 (ddd, J=8.2, 2.1, 0.7 Hz, 1H), 1.46 (s, 6H). ¹³C NMR (126 MHz, CDCl₃) δ 191.24, 155.15, 153.57, 147.22, 146.99, 146.60, 140.93, 140.60, 139.75, 138.93, 138.84, 138.17, 136.07, 135.13, 134.42, 133.53, 132.74, 130.75, 128.75, 128.49, 127.97, 127.79, 127.58, 126.97, 126.82, 126.64, 126.51, 126.36, 125.36, 124.47, 124.20, 123.94, 123.77, 123.60, 122.47, 120.68, 120.60, 120.54, 119.45, 118.88, 118.48, 109.71, 109.58, 46.88, 27.12.

### Synthesis of N-([1,1′-biphenyl]-4-yl)-9,9-dimethyl-N-(4-(9-(3-vinylphenyl)-9H-carbazol-3-yl)phenyl)-9H-fluoren-2-amine (A Monomer)

Under a blanket of nitrogen, a round bottom flask was charged with methyltriphenylphosphonium bromide (14.14 g, 39.58 mmol, 2.00 equiv) and 80 mL dry THF. Potassium tert-butoxide (5.55 g, 49.48 mmol, 2.50 equiv) was added in once portion, and the mixture stirred for 15 minutes. Aldehyde (13.99 g, 19.79 mmol, 1.00 equiv) was added in 8 mL dry THF. The slurry stirred at room temperature overnight. The solution was diluted with dichloromethane, and filtered through a plug of silica. The pad was rinsed with several portions of dichloromethane. The filtrate was adsorbed onto silica and purified by chromatography twice (10 to 30% dichloromethane in hexanes), which delivered product as a white solid (9.66 g, 67%) Purity was raised to 99.7% by reverse phase chromatography. ¹H NMR (400 MHz, CDCl₃) δ 8.35 (d, J=1.7 Hz, 114), 8.18 (dt, J=7.7, 1.0 Hz, 1H), 7.68-7.39 (m, 19H), 7.34-7.23 (m, 9H), 7.14 (dd, J=8.1, 2.1 Hz, 1H), 6.79 (dd, J=17.6, 10.9 Hz, 1H), 5.82 (d, J=17.6 Hz, 1H), 5.34 (d, J=10.8 Hz, 1H), 1.45 (s, 6H). ¹³C NMR (101 MHz, CDCl₃) δ 155.13, 153.57, 147.26, 147.03, 146.44, 141.29, 140.61, 140.13, 139.55, 138.95, 137.99, 136.36, 135.98, 135.06, 134.36, 132.96, 130.03, 128.74, 127.97, 127.77, 126.96, 126.79, 126.63, 126.49, 126.31, 126.11, 125.34, 125.16, 124.67, 124.54, 123.90, 123.55, 123.49, 122.46, 120.67, 120.36, 120.06, 119.44, 118.83, 118.33, 115.27, 110.01, 109.90, 46.87, 27.12. Lab Notebook Reference EXP-15-BD3509.

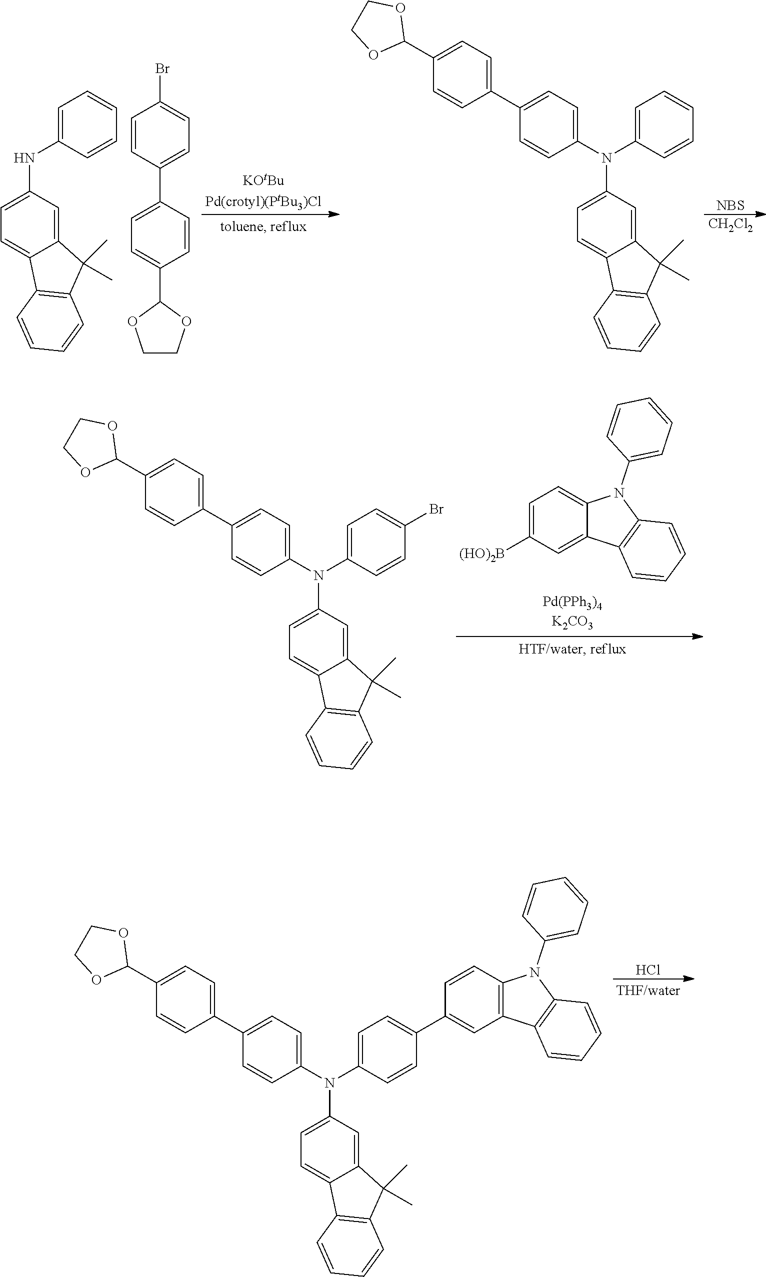

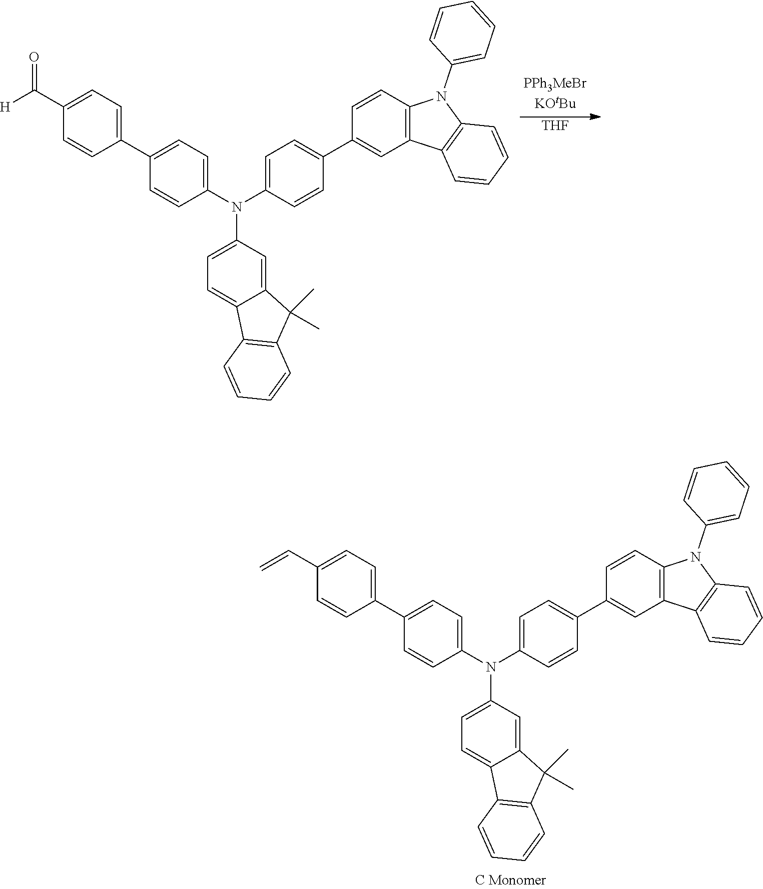

### Synthesis of N-(4′-(1,3-dioxolan-2-yl)-[1,1′-biphenyl]-4-yl)-9,9-dimethyl-N-phenyl-9H-fluoren-2-amine

A 500 mL round bottom flask was charged with 9,9-dimethyl-N-phenyl-9H-fluoren-2-amine (9.91 g, 34.7 mmol, 1.00 equiv), 2-(4′-bromo-[1,1′-biphenyl]-4-yl)-1,3-dioxolane (3.10 g, 7.78 mmol, 1.00 equiv), potassium tert-butoxide (1.31 g, 11.68 mmol, 1.50 equiv), and Pd(crotyl)(P^{t}Bu₃)Cl (0.062 g, 0.16 mmol, 2 mol %). The flask was connected to a reflux condenser and was placed under an atmosphere of nitrogen. 40 mL of dry, nitrogen-sparged toluene was added, and the solution was stirred at 120° C. for overnight. The solution was cooled and filtered through a pad of silica. The silica pad was rinsed with several portions of dichloromethane. The filtrate was adsorbed onto silica and purified by chromatography (10 to 80% dichloromethane in hexanes), which yielded product as a white solid (13.69 g, 73%). ¹H NMR (500 MHz, CDCl₃) δ 7.64 (d, J=7.3 Hz, 1H), 7.62-7.56 (m, 3H), 7.52 (d, J=8.3 Hz, 2H), 7.48 (d, J=8.8 Hz, 2H), 7.38 (d, J=7.4 Hz, 1H), 7.33-7.21 (m, 5H), 7.20-7.14 (m, 4H), 7.09-7.00 (m, 2H), 5.85 (s, 1H), 4.21-3.97 (m, 4H), 1.42 (s, 6H). ¹³C NMR (126 MHz, CDCl₃) δ 155.07, 153.52, 147.73, 147.46, 147.00, 141.53, 138.89, 136.27, 134.43, 134.36, 129.26, 127.76, 126.94, 126.86, 126.58, 126.48, 124.36, 123.62, 123.57, 122.90, 122.44, 120.62, 119.42, 118.85, 103.63, 65.30, 46.81, 27.06

### Synthesis of N-(4′-(1,3-dioxolan-2-yl)-[1,1′-biphenyl]-4-yl)-N-(4-bromophenyl)-9,9-dimethyl-9H-fluoren-2-amine

A round bottom flask was charged with N-(4′-(1,3-dioxolan-2-yl)-[1,1′-biphenyl]-4-yl)-9,9-dimethyl-N-phenyl-9H-fluoren-2-amine (13.7 g, 26.8 mmol, 1.00 equiv). The solid was dissolved in 130 mL of dichloromethane. The mixture was stirred vigorously and N-bromosuccinimide (4.77 g, 26.8 mmol, 1.00 equiv) was added in portions over 30 minutes. The mixture stirred for 24 hours, and was judged complete by TLC. The solution was washed with 1 M NaOH, dried with MgSO₄, and concentrated. The residue was purified by chromatography (30 to 90% dichloromethane in hexanes), which delivered product as a pale yellow solid (15.49 g, 95%). ¹H NMR (400 MHz, CDCl₃) δ 7.64 (ddd, J=7.4, 1.4, 0.7 Hz, 1H), 7.62-7.56 (m, 3H), 7.56-7.51 (m, 2H), 7.51-7.46 (m, 2H), 7.41-7.19 (m, 6H), 7.15 (d, J=6.7 Hz, 2H), 7.07-7.00 (m, 3H), 5.84 (s, 1H), 4.19-3.99 (m, 4H), 1.42 (s, 6H). ¹³C NMR (101 MHz, CDCl₃) δ 155.23, 153.52, 146.93, 146.91, 146.48, 141.36, 138.71, 136.45, 135.04, 134.85, 132.20, 127.91, 126.98, 126.88, 126.66, 126.61, 125.37, 123.92, 123.71, 122.46, 120.75, 119.50, 119.01, 115.01, 103.59, 65.30, 46.85, 27.05.

### Synthesis of N-(4′-(1,3-dioxolan-2-yl)-[1,1′-biphenyl]-4-yl)-9,9-dimethyl-N-(4-(9-phenyl-9H-carbazol-3-yl)phenyl)-9H-fluoren-2-amine

A round bottom flask was charged with the N-(4′-(1,3-dioxolan-2-yl)-[1,1′-biphenyl]-4-yl)-N-(4-bromophenyl)-9,9-dimethyl-9H-fluoren-2-amine (15.1 g, 25.7 mmol, 1.00 equiv), (9-phenyl-9H-carbazol-3-yl)boronic acid (9.58 g, 33.4 mmol, 1.30 equiv), potassium carbonate (10.6 g, 77.0 mmol, 3.00 equiv), and Pd(PPh₃)₄ (0.593 g, 0.513 mmol, 2 mol %). The flask was connected to a reflux condenser and was placed under an atmosphere of nitrogen. 130 mL of nitrogen-sparged 4:1 THF:water was added, and the solution was stirred at 70° C. overnight. The solution was cooled and diluted with water and dichloromethane. Product was extracted with several portions of dichloromethane, and combined organic fractions were dried with MgSO₄. The residue was purified by chromatography (25 to 100% dichloromethane in hexanes), which delivered product as a yellow solid (17.21 g, 82%). ¹H NMR (500 MHz, CDCl₃) δ 8.39-8.31 (m, 1H), 8.18 (dt, J=7.7, 1.1 Hz, 1H), 7.66-7.56 (m, 11H), 7.56-7.48 (m, 4H), 7.48-7.38 (m, 5H), 7.33-7.22 (m, 8H), 7.13 (dd, J=8.2, 2.1 Hz, 1H), 5.85 (s, 1H), 4.20-3.98 (m, 4H), 1.45 (s, 6H). ¹³C NMR (126 MHz, CDCl₃) δ 155.13, 153.56, 147.43, 146.96, 146.36, 141.55, 141.29, 140.14, 138.92, 137.64, 136.45, 136.29, 134.50, 134.40, 132.89, 129.87, 127.97, 127.81, 127.44, 127.01, 126.96, 126.88, 126.60, 126.49, 126.07, 125.12, 124.61, 123.88, 123.74, 123.59, 123.45, 122.46, 120.67, 120.33, 120.01, 119.44, 118.86, 118.31, 109.99, 109.88, 103.64, 65.31, 46.87, 27.11.

### Synthesis of 4′-((9,9-dimethyl-9H-fluoren-2-yl)(4-(9-phenyl-9H-carbazol-3-yl)phenyl)amino)-[1,1′-biphenyl]-4-carbaldehyde

A round bottom flask was charged with N-(4′-(1,3-dioxolan-2-yl)-[1,1′-biphenyl]-4-yl)-9,9-dimethyl-N-(4-(9-phenyl-9H-carbazol-3-yl)phenyl)-9H-fluoren-2-amine (17.21 g, 22.92 mmol, 1.00 equiv). 115 mL tetrahydrofuran was added, followed by aq. HCl (1.00 M, 45.8 mL, 2.00 equiv). The flask was connected to a reflux condenser and was stirred for 5 hours at 70° C. The solution was cooled, product was extracted with three portions of dichloromethane. Combined organic fractions were washed with water, then sat. aq. NaHCO₃. The solution was dried with MgSO₄, and adsorbed onto silica for purification by chromatography, which yielded the product as a yellow solid (16.0 g, 95%). Higher purity (>99.5%) material could be obtained by reverse phase chromatography. ¹H NMR (400 MHz, CDCl₃) δ 10.02 (s, 1H), 8.36 (dd, J=1.8, 0.6 Hz, 1H), 8.18 (dt, J=7.7, 1.0 Hz, 1H), 7.92 (d, J=8.3 Hz, 2H), 7.75 (d, J=8.3 Hz, 2H), 7.69-7.53 (m, 11H), 7.51-7.38 (m, 5H), 7.36-7.21 (m, 8H), 7.15 (dd, J=8.1, 2.1 Hz, 1H), 1.46 (s, 6H). ¹³C NMR (101 MHz, CDCl₃) δ 191.82, 155.24, 153.58, 148.50, 146.62, 146.57, 146.03, 141.32, 140.21, 138.81, 137.63, 136.97, 134.88, 134.65, 132.77, 132.71, 130.33, 129.89, 128.08, 128.04, 127.49, 127.02, 126.85, 126.67, 126.12, 125.12, 124.99, 123.97, 123.90, 123.43, 123.14, 122.50, 120.77, 120.32, 120.05, 119.53, 119.26, 118.36, 110.03, 109.92, 46.90, 27.11.

### Synthesis of 9,9-dimethyl-N-(4-(9-phenyl-9H-carbazol-3-yl)phenyl)-N-(4′-vinyl-[1,1′-biphenyl]-4-yl)-9H-fluoren-2-amine (C Monomer)

Under a blanket of nitrogen, a round bottom flask was charged with methyltriphenylphosphonium bromide (16.17 g, 45.27 mmol, 2.00 equiv) and 100 mL dry THF. Potassium tert-butoxide (6.35 g, 56.6 mmol, 2.50 equiv) was added in once portion, and the mixture stirred for 15 minutes. 4′-((9,9-dimethyl-9H-fluoren-2-yl)(4-(9-phenyl-9H-carbazol-3-yl)phenyl)amino)-[1,1′-biphenyl]-4-carbaldehyde (16.00 g, 22.63 mmol, 1.00 equiv) was added in 50 mL dry THF. The slurry stirred at room temperature overnight. The solution was quenched with 1 mL of water, and the mixture was filtered through a pad of silica. The pad was rinsed with several portions of dichloromethane. The filtrate was adsorbed to silica, and purified by chromatography (30% dichloromethane in hexane), which delivered product as a white solid (10.18 g, 63%). Reverse phase chromatography brought purity to 99.5%. ¹H NMR (500 MHz, CDCl₃) δ 8.35 (d, J=1.7 Hz, 1H), 8.18 (dd, J=7.8, 1.0 Hz, 1H), 7.67-7.55 (m, 11H), 7.54-7.50 (m, 2H), 7.48-7.37 (m, 7H), 7.33-7.21 (m, 8H), 7.13 (dd, J=8.1, 2.0 Hz, 1H), 6.74 (dd, J=17.6, 10.9 Hz, 1H), 5.77 (dd, J=17.6, 0.9 Hz, 1H), 5.25 (dd, J=10.9, 0.8 Hz, 1H), 1.45 (s, 6H). ¹³C NMR (126 MHz, CDCl₃) δ 155.14, 153.56, 147.31, 146.98, 146.38, 141.30, 140.15, 139.97, 138.93, 137.65, 136.44, 136.08, 134.46, 134.39, 132.90, 129.88, 127.98, 127.56, 127.45, 127.02, 126.97, 126.64, 126.63, 126.50, 126.08, 125.12, 124.59, 123.89, 123.82, 123.57, 123.47, 122.47, 120.68, 120.34, 120.02, 119.45, 118.84, 118.31, 113.56, 110.00, 109.89, 46.87, 27.12.

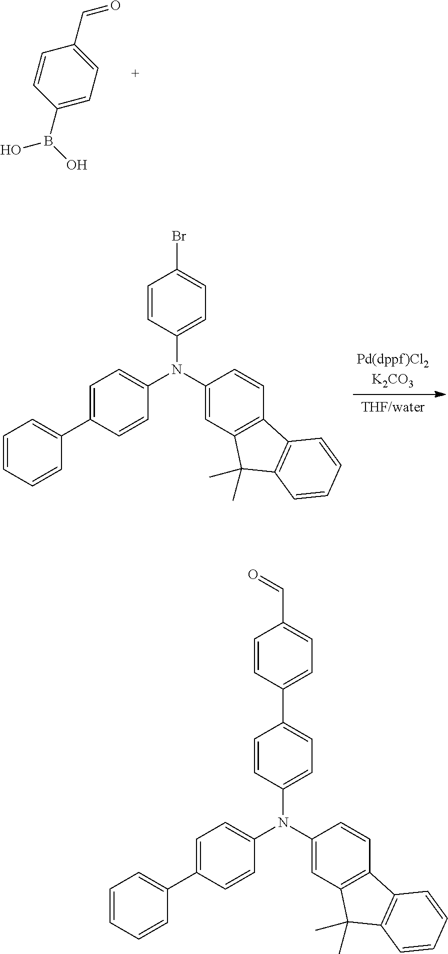

### Synthesis of 4′-([1,1′-biphenyl]-4-yl(9,9-dimethyl-9H-fluoren-2-yl)amino)-[1,1′-biphenyl]-4-carbaldehyde

A 500 mL, 3-neck round bottom flask, fitted with a thermocouple, a condenser with an N₂ inlet, and a septum was charged with N-([1,1′-biphenyl]-4-yl)-N-(4-bromophenyl)-9,9-dimethyl-9H-fluoren-2-amine (18 g, 34.6 mmol, 1 equiv.), 4-formylphenylboronic acid (5.75 g, 38.3 mmol, 1 equiv.), tetrahydrofuran (285 mL), and 2 M aqueous K₂CO₃ (52 mL). The mixture was stirred and sparged with N₂ for 30 minutes. Pd(dppf)Cl₂ (0.51 g, 0.70 mmol, 0.02 equiv.) was added, and the reaction was heated to reflux for 21 h. Tetrahydrofuran was distilled away, and the reaction was diluted with water (300 mL) and extracted with dichloromethane (2×300 mL). The combined organic phases were dried of MgSO₄, filtered and condensed on to silica. The material was chromatographed using a gradient eluent (1 column volume hexanes increasing to 1:1 hexanes:dichloromethane over 8 column volumes, then maintaining the 1:1 ratio for 10 column volumes). Combined fractions were condensed to yield a bright yellow solid (7.41 g at 99.6% purity, 7.24 g at 98.9% purity, combined yield: 77%). ¹H NMR (400 MHz, C₆D6) δ 9.74 (s, 1H), 7.61 (2H, dd, J=8 Hz, 2 Hz), 7.55 (2H, dd, J=20 Hz, 2.4 Hz), 7.50-7.46 (5H, multiple peaks), 7.37-7.11 (15H, multiple peaks), 1.28 (s, 6H). ¹³C NMR (101 MHz, C₆D6) δ 190.64, 155.70, 153.83, 148.64, 147.24, 147.05, 146.04, 140.76, 139.10, 136.52, 135.61, 135.38, 133.68, 130.22, 129.01, 128.43, 128.36, 127.39, 127.18, 127.12, 126.95, 126.94, 124.93, 124.44, 123.82, 122.74, 121.29, 119.88, 119.61, 46.95z, 26.93.

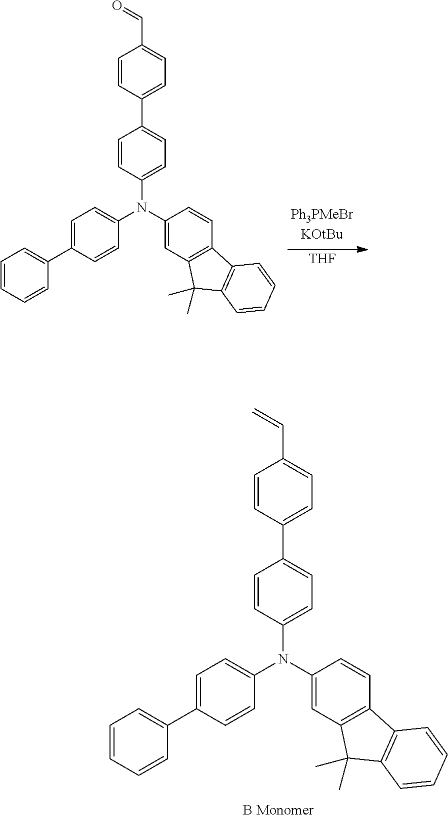 [SMILES: CC1(C)c2ccccc2-c2ccc(N(c3ccc(-c4ccccc4)cc3)c3ccc(-c4ccc(C=O)cc4)cc3)cc21 ; C=Cc1ccc(-c2ccc(N(c3ccc(-c4ccccc4)cc3)c3ccc4c(c3)C(C)(C)c3ccccc3-4)cc2)cc1 ; "THF"]

### Synthesis of N-([1,1′-biphenyl]-4-yl)-9,9-dimethyl-N-(4′-vinyl-[1,1′-biphenyl]-4-yl)-9H-fluoren-2-amine (B Monomer)

A 250 mL round bottom flask 3-neck roundbottom flask, fitted with a thermocouple, a condenser with an N₂ inlet, and a septum was charged with methyltriphenylphosphonium bromide (5.3 g, 5.28 mmol, 2 equiv.) and dry tetrahydrofuran (34 mL). Potassium tert-butoxide (2.08 g, 18.4 mmol, 2.5 equiv.) was added, and the mixture stirred for 15 minutes. 4′-([1,1′-biphenyl]-4-yl(9,9-dimethyl-9H-fluoren-2-yl)amino)-[1,1′-biphenyl]-4-carbaldehyde (3.94 g, 7.3 mmol, 1 equiv.) was dissolved in dry tetrahydrofuran (17 mL) and added to the methyltriphenylphosphonium bromide solution. The reaction was stirred for 16 h at room temperature. Water (0.5 mL) was added, and the mixture was filtered through a pad of silica. The pad was rinsed with dichloromethane, and the filtrate was adsorbed to silica and purified by chromatography using a gradient eluent (1 column volume hexanes increasing to 80:20 hexanes:dichloromethane over 19 column volumes, then maintaining the 80:20 ratio for 10 column volumes). The combined fractions were condensed to yield a white solid (2.62 g at 99.8% purity was isolated, 67% yield). ¹H NMR (400 MHz, C₆D6) δ 7.55-7.43 (multiple peaks, 11H), 7.33-7.10 (multiple peaks 13H), 6.63 (1H, dd, J=20 Hz, 12 Hz) 5.66 (1H, dd, J=20 Hz, 1.2 Hz), 5.11 (1H, dd, J=12 Hz, 1.2 Hz), 1.27 (s, 6H). ¹³C NMR (101 MHz, C₆D6) δ 155.61, 153.85, 147.66, 147.57, 147.39, 140.91, 140.28, 139.25, 136.82, 136.51, 136.04, 135.41, 135.19, 128.98, 128.28, 128.02, 127.78, 127.34, 127.04, 127.02, 126.98, 126.94, 124.60, 124.52, 124.15, 122.71, 121.23, 119.81, 119.30, 113.42, 46.93, 26.94.

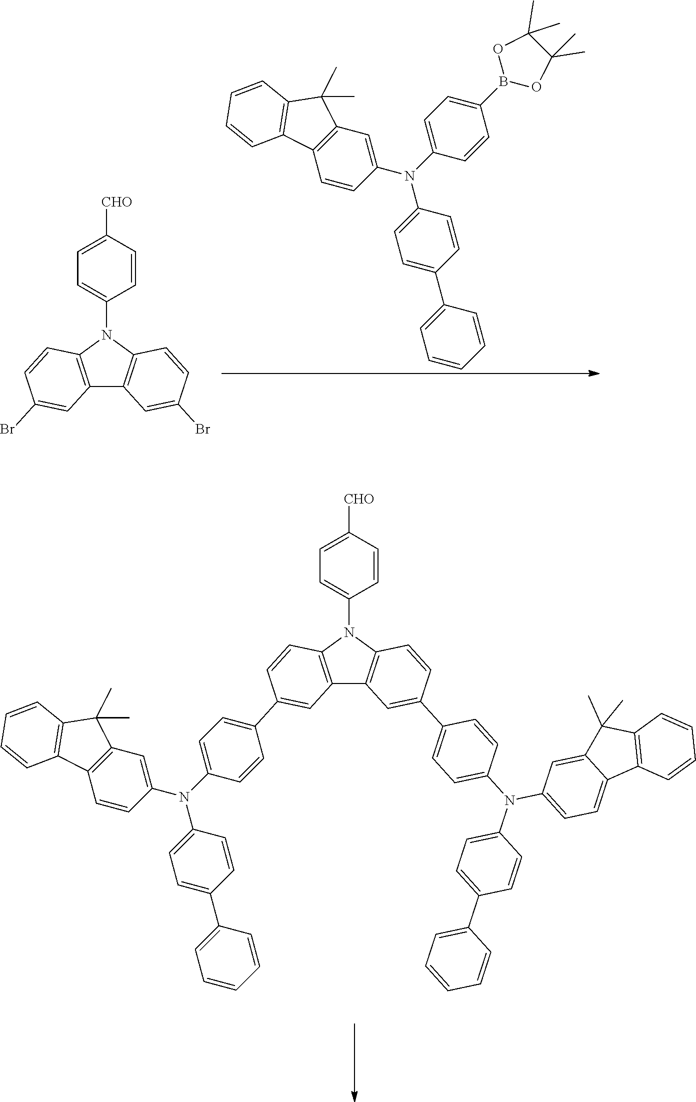 [SMILES: O=Cc1ccc(-n2c3ccc(Br)cc3c3cc(Br)ccc32)cc1 ; CC1(C)c2ccccc2-c2ccc(N(c3ccc(B4OC(C)(C)C(C)(C)O4)cc3)c3ccc(-c4ccccc4)cc3)cc21 ; CC1(C)c2ccccc2-c2ccc(N(c3ccc(-c4ccccc4)cc3)c3ccc(-c4ccc5c(c4)c4cc(-c6ccc(N(c7ccc(-c8ccccc8)cc7)c7ccc8c(c7)C(C)(C)c7ccccc7-8)cc6)ccc4n5-c4ccc(C=O)cc4)cc3)cc21]

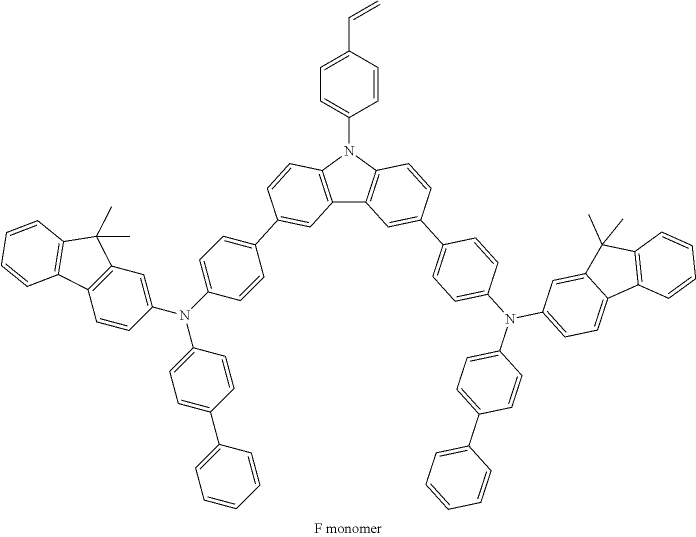 [SMILES: C=Cc1ccc(-n2c3ccc(-c4ccc(N(c5ccc(-c6ccccc6)cc5)c5ccc6c(c5)C(C)(C)c5ccccc5-6)cc4)cc3c3cc(-c4ccc(N(c5ccc(-c6ccccc6)cc5)c5ccc6c(c5)C(C)(C)c5ccccc5-6)cc4)ccc32)cc1]

### Synthesis of 4-(3,6-bis(4-([1,1′-biphenyl]-4-yl(9,9-dimethyl-9H-fluoren-2-yl)amino)phenyl)-9H-carbazol-9-yl)benzaldehyde

A mixture of 4-(3,6-dibromo-9H-carbazol-9-yl)benzaldehyde (6.00 g, 17.74 mmol), N-([1,1′-biphenyl]-4-yl)-9,9-dimethyl-N-(4-(4,4,5,5-tetramethyl-1,3,2-dioxaborolan-2-yl)phenyl)-9H-fluoren-2-amine (15.70 g, 35.49 mmol), Pd(PPh3)3 (0.96 g), 7.72 g K2CO3, 100 mL THF and 30 mL H2O was heated at 80° C. under nitrogen overnight. After cooled to room temperature, the solvent was removed under vacuum and the residue was extracted with dichloromethane. The product was then obtained by column chromatography on silica gel with petroleum ether and dichloromethane as eluent, to provide desired product (14.8 g, yield 92%). ¹H NMR (CDCl₃, ppm): 10.14 (s, 1H), 8.41 (d, 2H), 8.18 (d, 2H), 7.86 (d, 2H), 7.71 (dd, 2H), 7.56-7.68 (m, 14H), 7.53 (m, 4H), 7.42 (m, 4H), 7.26-735 (m, 18H), 7.13-7.17 (d, 2H), 1.46 (s 12H).

### (4-(3,6-bis(4-([1,1′-biphenyl]-4-yl(9,9-dimethyl-9H-fluoren-2-yl)amino)phenyl)-9H-carbazol-9-yl)phenyl)methanol

4-(3,6-bis(4-([1,1′-biphenyl]-4-yl(9,9-dimethyl-9H-fluoren-2-yl)amino)phenyl)-9H-carbazol-9-yl)benzaldehyde (10.0 g, 8.75 mmol) was dissolved into 80 mL THF and 30 mL ethanol. NaBH₄ (1.32 g, 35.01 mmol) was added under nitrogen atmosphere over 2 hours. Then, aqueous hydrochloric acid solution was added until pH 5 and the mixture was kept stirring for 30 min. The solvent was removed under vacuum and the residue was extracted with dichloromethane. The product was then dried under vacuum and used for the next step without further purification.

Synthesis of F Monomer

Under N₂ atomsphere, PPh₃CMeBr (1.45 g, 4.0 mmol) was charged into a three-neck round-bottom flask equipped with a stirrer, to which 180 mL anhydrous THF was added. The suspension was placed in an ice bath. Then t-BuOK (0.70 g, 6.2 mmol) was added slowly to the solution, the reaction mixture turned into bright yellow. The reaction was allowed to react for an additional 3 h. After that, 4-(3,6-bis(4-([1,1′-biphenyl]-4-yl(9,9-dimethyl-9H-fluoren-2-yl)amino)phenyl)-9H-carbazol-9-yl)benzaldehyde (2.0 g, 1.75 mmol) was charged into the flask and stirred at room temperature overnight. The mixture was quenched with 2N HCl, and extracted with dichloromethane, and the organic layer was washed with deionized water three times and dried over anhydrous Na₂SO₄. The filtrate was concentrated and purified on silica gel column using dichloromethane and petroleum ether (1:3) as eluent. The crude product was further recrystallized from dichloromethane and ethyl acetate with purity of 99.8%. ESI-MS (m/z, Ion): 1140.523, (M+H)⁺. ¹H NMR (CDCl₃, ppm): 8.41 (s, 2H), 7.56-7.72 (m, 18H), 7.47-7.56 (m, 6H), 7.37-7.46 (m, 6H), 7.23-7.36 (m, 18H), 6.85 (q, 1H), 5.88 (d, 1H), 5.38 (d, 1H), 1.46 (s, 12H).

General Protocol for Radical Polymerization of Charge Transporting Monomers:

In a glovebox, charge transporting monomer (1.00 equiv) was dissolved in anisole (electronic grade, 0.25 M). The mixture was heated to 70° C., and AIBN solution (0.20 M in toluene, 5 mol %) was injected. The mixture was stirred until complete consumption of monomer, at least 24 hours (2.5 mol % portions of AIBN solution can be added to complete conversion). The polymer was precipitated with methanol (10× volume of anisole) and isolated by filtration. The filtered solid was rinsed with additional portions of methanol. The filtered solid was re-dissolved in anisole and the precipitation/filtration sequence repeated twice more. The isolated solid was placed in a vacuum oven overnight at 50° C. to remove residual solvent.

Purity and halide analyses of the anisole used in these examples was as follows:

| | purity | halide | metal |
|---|---|---|---|
| anisole | 100% | 0.44 ppm | 9.85 ppb |

* specification limits

### Molecular Weights of the Polymers were as Follows

| polymer | Mₙ | M_{w} | M_{z} | M_{z+1} | PDI |
|---|---|---|---|---|---|
| A | 23,413 | 88,953 | 53,826 | 80,886 | 3.80 |
| B | 11,938 | 28,899 | 13,254 | 22,789 | 2.42 |
| C | 22,348 | 93,724 | 196,464 | 302,526 | 4.19 |
| F | 15,704 | 61,072 | 124,671 | 227,977 | 3.89 |

General Experimental Procedures for OLED Device Manufacturing and Testing

To evaluate electroluminescent (EL) performances of the charge transporting polymers as a Hole Transporting Layer (HTL) in presence of acid p-dopant, the following types of OLED devices were fabricated for exploring the acid p-doping effect:
Type A ITO/AQ1200/HTL molecule (evaporative, 400 Å)/EML/ETL/Al
Type B: ITO/AQ1200/HTL polymer (soluble, 400 Å)/EML/ETL/Al
Type C: ITO/AQ1200/HTL polymer+acid p-dopant (soluble 4.00 Å)/EML/ETL/Al

The thicknesses of the Hole Injection Layer (HIL), Emission Material Layer (EML), Electron Transporting Layer (ETL) and cathode Al are 470, 400, 350 and 800 Å, respectively. Type A device was fabricated with evaporated HTL (same HTL core as HTL polymer) as evaporative control; Type B device was fabricated with solution processed HTL polymer as soluble control; Type C device was fabricated with solution processed HTL polymer plus 2 to 10 wt % acid p-dopant. Current density-voltage (J-V) characteristics, luminescence efficiency versus luminance curves, and luminescence decay over time curves of Type A-C devices were measured to evaluate the key device performance, specifically the driving voltage (at 1000 nit), current efficiency (at 1000 nit) and lifetime (15000 nit, after 10 hr). Type A to C Hole-Only Device (HOD) without EML and ETL layers were also prepared and tested for evaluating the hole mobility of the acid p-doped HTL.

### Example 1: HB Doped High MW A and Medium MW B—HOD Device

HB doped high MW A and medium MW B homopolymers give higher hole mobility than high MW A and medium MWB in terms of lower driving voltage at 10 and 100 mA/cm².
HB doped high MW A and medium MW B homopolymers give better p-doping effect at lower HTL annealing temperature in term of lower driving voltage at 10 and 100 mA/cm².

TABLE 1
Summary table on A, B + HB as HTL in HOD

| | | | Thermal | | Voltage |
|---|---|---|---|---|---|
| HOD | Device Structure | | Annealing | | [V@10/100 |
| Device | HIL | HTL | HIL | HTL | mA/cm²] |
| Control | PLEXCORE | A | 150° C. | 150° C. | 2.5/3.5 |
| | AQ1200 | | | | |
| Sample | PLEXCORE | A + 2 wt % | 150° C. | 150° C. | 1.5/2.6 |
| | AQ1200 | HB | | | |
| Control | PLEXCORE | A | 150° C. | 205° C. | 3.0/4.5 |
| | AQ1200 | | | | |
| Sample | PLEXCORE | A + 2 wt % | 150° C. | 205° C. | 2.3/3.3 |
| | AQ1200 | HB | | | |
| Control | PLEXCORE | B | 150° C. | 150° C. | 3.0/3.9 |
| | AQ1200 | | | | |
| Sample | PLEXCORE | B + 2 wt % | 150° C. | 150° C. | 2.1/3.0 |
| | AQ1200 | HB | | | |
| Control | PLEXCORE | B | 150° C. | 205° C. | 3.4/4.7 |
| | AQ1200 | | | | |
| Sample | PLEXCORE | B + 2 wt % | 150° C. | 205° C. | 3.0/4.0 |
| | AQ1200 | HB | | | |

1. A single liquid phase formulation useful for producing an organic charge transporting film; said formulation comprising: (a) a polymer having Mₙ at least 4,000 and comprising polymerized units of a compound of formula NAr¹Ar²Ar³, wherein Ar¹, Ar² and Ar³ independently are C₆-C₅₀ aromatic substituents and at least one of Ar¹, Ar² and Ar³ contains a vinyl group attached to an aromatic ring; provided that said compound contains no arylmethoxy linkages; (b) an acid catalyst which
is an organic Bronsted acid with pKa≤4; a Lewis acid comprising a positive aromatic ion and an anion which is (i) a tetraaryl borate having the formula 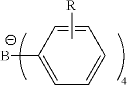
wherein R represents zero to five non-hydrogen substituents selected from D, F and CF₃, (ii) BF₄⁻, (iii) PF₆⁻, (iv) SbF₆⁻, (v) AsF₆⁻ or (vi) ClO₄⁻; or a thermal acid generator which is an ammonium or pyridinium salt of an organic Bronsted acid with pKa≤2 or an ester of an organic sulfonic acid; and (c) a solvent.

2. The formulation of claim 1 in which the polymer has Mₙ at least 5,000.

3. The formulation of claim 2 comprising from 0.5 to 10 wt % polymer, from 0.01 to 1 wt % acid catalyst and from 90 to 99.5 wt % solvent.

4. The formulation of claim 3 in which the solvent or solvent blend has a Hansen RED value less than 1.2 relative to the polymer.

5. A method of making an organic charge transporting film; said method comprising steps of: (a) coating on a surface a formulation comprising: (i) a polymer having Mₙ at least 4,000 and comprising polymerized units of a compound of formula NAr¹Ar²Ar³, wherein Ar¹, Ar² and Ar³ independently are C₆-C₅₀ aromatic substituents and at least one of Ar¹, Ar² and Ar³ contains a vinyl group attached to an aromatic ring, provided that said compound has no arylmethoxy linkages; (ii) an acid catalyst
which
is an organic Bronsted acid with pKa≤4; a Lewis acid comprising a positive aromatic ion and an anion which is (i) a tetraaryl borate having the formula 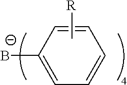
wherein R represents zero to five non-hydrogen substituents selected from D, F and CF₃, (ii) BF₄⁻, (iii) PF₆⁻, (iv) SbF₆⁻, (v) AsF₆⁻ or (vi) ClO₄⁻; or a thermal acid generator which is an ammonium or pyridinium salt of an organic Bronsted acid with pKa≤2 or an ester of an organic sulfonic acid; and (iii) a solvent; and (b) heating the coated surface to a temperature from 120 to 280° C.

6. The method of claim 5 in which the polymer has Mₙ at least 5,000.

7. The method of claim 6 in which the formulation comprises from 0.5 to 10 wt % polymer, from 0.01 to 1 wt % acid catalyst and from 90 to 99.5 wt % solvent.

8. The method of claim 7 in which in which the solvent or solvent blend has a Hansen RED value less than 1.2 relative to the polymer.

9. The method of claim 8 in which the coated surface is heated to a temperature from 140 to 230° C.

10. An electronic device comprising one or more organic charge transporting films made by the method of claim 5.

11. A light emitting device comprising one or more organic charge transporting films made by the method of claim 5.
